(19) United States
(12) Patent Application Publication
(10) Pub. No.: US 2026/0033052 A1
(43) Pub. Date: Jan. 29, 2026

(54) LIGHT-EMITTING DIODE AND LIGHT-EMITTING DEVICE

(71) Applicant: QUANZHOU SANAN SEMICONDUCTOR TECHNOLOGY CO., LTD., Quanzhou (CN)

(72) Inventors: Jun WANG, Quanzhou (CN); Lingwei WANG, Quanzhou (CN)

(21) Appl. No.: 19/276,036

(22) Filed: Jul. 22, 2025

(30) Foreign Application Priority Data
Jul. 23, 2024 (CN) 202410994651.0

(51) Int. Cl. H10H 20/857; H10H 20/831

(52) U.S. Cl. CPC H10H 20/857; H10H 20/8312

(57) ABSTRACT

A light-emitting diode includes a substrate; a multi-layer structure, stacked on the substrate, sequentially includes a first electrical connection layer, an insulating layer, a second electrical connection layer and a semiconductor light-emitting sequence including a first semiconductor layer, an active layer and a second semiconductor layer, the first electrical connection layer is in contact with the first semiconductor layer, and the second electrical connection layer is electrically connected to the second semiconductor layer; a first electrode, electrically connected to the first semiconductor layer; a second electrode, electrically connected to the second semiconductor layer; an intermediate layer, located between the substrate and the first electrode; and a metal protective layer, extending from a side of the first electrical connection layer through the first electrical connection layer and the insulating layer to contact with the intermediate layer, and including at least one metal element different from the first electrical connection layer.

### CROSS-REFERENCE TO RELATED APPLICATION

This application claims priority to Chinese Patent Application No. 202410994651.0, filed on Jul. 23, 2024, which is herein incorporated by reference in its entirety.

### TECHNICAL FIELD

The disclosure relates to the technical field of semiconductor devices, and more particularly to a light-emitting diode and a light-emitting device.

### BACKGROUND

In a horizontal-vertical structure light-emitting diode, a support substrate supports a backside of a semiconductor sequence. A PN electrical connection layer is located between the support substrate and the semiconductor sequence. PN electrodes are let out from a backside of a light-emitting surface of the semiconductor sequence through connection to the PN electrical connection layer. This configuration ensures uniform current spreading under high-current operation without obscuring the light output, thereby providing superior luminous efficacy.

In current horizontal-vertical structure light-emitting diode, the PN electrical connection layer is insulated and isolated through an insulating layer. A P electrical connection layer is electrically connected to a P-type layer of the semiconductor sequence, while a N electrical connection layer is electrically connected to a N-type layer of the semiconductor sequence. An intermediate layer is disposed between a lower part of the N electrode and the substrate. A material of the intermediate layer is the same as that of the P electrical connection layer. A portion of the N electrical connection layer passes through the insulating layer and is connected to the intermediate layer, thereby achieving the electrical connection between the N electrode and the N-type layer. In order to achieve good conductivity, the intermediate layer mainly includes a metal material gold (Au). In order to improve a light extraction efficiency, the electrical connection layer of the N electrode mainly includes metals with a high reflectivity, such as aluminum (Al), chromium (Cr), silver (Ag) or their alloy. However, it is found that in a conventional horizontal-vertical structure chip bonding process, under an action of thermo-mechanical stresses, a contact part of the N electrical connection layer below the N electrode and the intermediate layer will easily cause Au to melt with metals such as Al, Cr, and Ag, which is further likely to cause high voltage of the chip, and even the risk of wire-bonding lift-off at the N electrode, resulting in loss of appearance and electrical yield.

Therefore, it is necessary to refine the design and improve the verification of the horizontal-vertical structure chips (i.e., the horizontal-vertical structure light-emitting diode) to avoid the above problems.

### SUMMARY

The disclosure provides a light-emitting diode, including a substrate, a multi-layer structure, a first electrode, a second electrode, an intermediate layer and a metal protective layer. The multi-layer structure is stacked on the substrate. The multi-layer structure, starting from a side of the substrate, sequentially includes at least a first electrical connection layer, an insulating layer, a second electrical connection layer and a semiconductor light-emitting sequence. The semiconductor light-emitting sequence, starting from a side far away from the substrate, sequentially includes a first semiconductor layer, an active layer and a second semiconductor layer. The first electrical connection layer is at least partially in contact with the first semiconductor layer. The second electrical connection layer is electrically connected to the second semiconductor layer. The first electrode is electrically connected to the first semiconductor layer through the first electrical connection layer. The second electrode is electrically connected to the second semiconductor layer through the second electrical connection layer. The semiconductor light-emitting sequence, the first electrode and the second electrode are disposed on a same side of the substrate. The intermediate layer is located between the substrate and the first electrode, and at least a portion of a surface of the intermediate layer is in contact with the first electrode. The metal protective layer extends from at least one side of the first electrical connection layer through the first electrical connection layer and the insulating layer to contact with the intermediate layer, and the metal protective layer includes at least one metal element different from the first electrical connection layer.

The disclosure further provides a light-emitting diode, including a substrate, a multi-layer structure, a first electrode, a second electrode, an intermediate layer and a metal protective layer. The multi-layer structure is stacked on the substrate. The multi-layer structure is stacked on the substrate. The multi-layer structure, starting from a side of the substrate, sequentially includes at least a first electrical connection layer, an insulating layer, a second electrical connection layer and a semiconductor light-emitting sequence. The semiconductor light-emitting sequence, starting from a side far away from the substrate, sequentially includes a first semiconductor layer, an active layer and a second semiconductor layer. The first electrical connection layer is at least partially in contact with the first semiconductor layer. The second electrical connection layer is electrically connected to the second semiconductor layer. The first electrode is electrically connected to the first semiconductor layer through the first electrical connection layer. The second electrode is electrically connected to the second semiconductor layer through the second electrical connection layer. The semiconductor light-emitting sequence, the first electrode and the second electrode are disposed on a same side of the substrate. The intermediate layer is located between the substrate and the first electrode, at least a portion of a surface of the intermediate layer is in contact with the first electrode, and the insulating layer defines an opening exposing the at least a portion of the surface of the intermediate layer. The metal protective layer is filled in the opening, and is in contact with the intermediate layer.

The disclosure further includes a light-emitting device, including a package substrate, and a surface of the package substrate includes at least two conductive layers insulated from each other. Any light-emitting diode described in the disclosure is fixed on the surface of the package substrate, the first electrode and the second electrode are respectively connected to the at least two conductive layers insulated from each other through metal wires, and the surface of the package substrate and a surface of the light-emitting diode are covered with package resin.

In the disclosure, by setting the metal protective layer inside the light-emitting diode, the intermediate layer can be isolated from the first electrical connection layer to avoid contact between the intermediate layer and the first electrical connection layer, thereby preventing the metal of the intermediate layer and the metal of the first electrical connection layer from fusing due to high temperature and high pressure in the subsequent bonding process, reducing the risk of voltage increase in the light-emitting diode and wire-bonding lift-off at the first electrode, and improving the reliability of the light-emitting diode.

### BRIEF DESCRIPTION OF DRAWINGS

FIG. 1 illustrates a schematic structural diagram of an existing light-emitting diode.

FIG. 2 illustrates a schematic structural diagram of a light-emitting diode according to an embodiment 1 of the disclosure.

FIGS. 3-11 illustrate schematic structural diagrams of structures obtained at each step in a manufacturing method of the light-emitting diode according to the embodiment 1 of the disclosure.

FIG. 12 illustrates a schematic diagram from a top perspective of the light-emitting diode according to the embodiment 1 of the disclosure.

FIG. 13 illustrates a schematic diagram from a top perspective of a side of a first electrical connection layer of a light-emitting diode according to an embodiment 2 of the disclosure.

FIG. 14 illustrates a schematic structural diagram of the light-emitting diode according to the embodiment 2 of the disclosure.

FIG. 15 illustrates another schematic diagram from a top perspective of a side of a first electrical connection layer of another light-emitting diode according to an embodiment 2 of the disclosure.

FIG. 16 illustrates a schematic structural diagram of another light-emitting diode according to the embodiment 2 of the disclosure.

FIG. 17 illustrates a schematic structural diagram of a light-emitting diode according to an embodiment 3 of the disclosure.

FIG. 18 illustrates a schematic structural diagram of a light-emitting device according to an embodiment 4 of the disclosure.

### DETAILED DESCRIPTION OF EMBODIMENTS

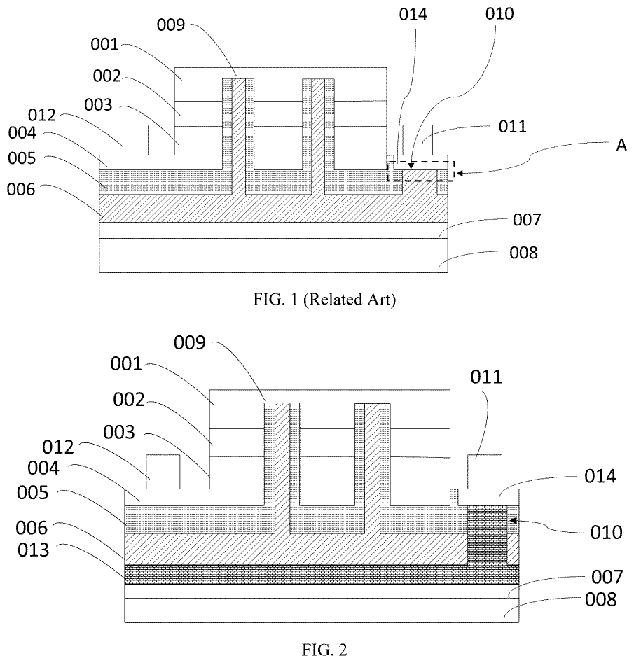

FIG. 1 illustrates a schematic sectional diagram of a horizontal-vertical structure light-emitting diode in the related art. A light-emitting diode includes a substrate 008 and a multi-layer structure on the substrate 008. The multi-layer structure, starting from a side of the substrate 008, sequentially includes a bonding layer 007, a first electrical connection layer 006, an insulating layer 005, a second electrical connection layer 004 and a semiconductor light-emitting sequence. The light-emitting diode further includes a first electrode 011 and a second electrode 012 for external bonding connection. The semiconductor light-emitting sequence, the first electrode 011 and the second electrode 012 are located on a same side of the substrate 008.

The semiconductor light-emitting sequence, starting from a side far away from the substrate 008, sequentially includes a first semiconductor layer 001, an active layer 002 and a second semiconductor layer 003. The semiconductor light-emitting sequence further includes at least one first through hole 009. The first through hole 009 defines an opening on a side of the second semiconductor layer 003, and extends through the second semiconductor layer 003 and the active layer 002 to the first semiconductor layer 001. The second electrical connection layer 004 is located on a side of the second semiconductor layer 003, and does not cover the opening of the first through hole 009. The insulating layer 005 extends from the opening of the first through hole 009 on a side of the second electrical connection layer 004 to cover a sidewall of the first through hole 009, and expose a bottom of the first through hole 009. The second electrical connection layer 004 is located on a side of the second semiconductor layer 003, and is electrically connected to the second semiconductor layer 003, and the second electrical connection layer 004 extends horizontally to a lower part of the second electrode 012, and is in contact with the second electrode 012. The second electrode 012 is electrically connected to the second semiconductor layer 003 through the second electrical connection layer 004.

The light-emitting diode further includes an intermediate layer 014, and the intermediate layer 014 is located between the first electrode 011 and the substrate 008, and is in contact with the first electrode 011. At least one second through hole 010 is defined below the intermediate layer 014, and the second through hole 010 defines an opening on a side of the insulating layer 005, and extends through the insulating layer 005 to the intermediate layer 014. The first electrical connection layer 006 covers a side surface of the insulating layer 005, and is filled in the first through hole 009 to the bottom of the first through hole 009 to contact with the first semiconductor layer 001. The first electrical connection layer 006 is further filled in the second through hole 010 to a bottom of the second through hole 010 to contact with the intermediate layer 014, thereby achieving the electrical connection between the first electrode 011 and the first semiconductor layer 001.

The first electrical connection layer 006 mainly includes metals with a high reflectivity, such as Al, Cr, Ag or their alloy. A material of the intermediate layer 014 is the same as that of the second electrical connection layer 004, generally including metal materials with good conductivity, such as Au. During a chip manufacturing process, the bonding layer 007 is tightly stacked with the first electrical connection layer 006, appropriate pressure is applied to the bonding layer 007 and the first electrical connection layer 006 by a bonding device, and the chip is placed in an annealing furnace for annealing. During the annealing process, diffusion and mutual melting occur between the metals of the bonding layer 007 and the first electrical connection layer 006, and the bonding layer 007 and the first electrical connection layer 006 are firmly bonded together through metal bonds and covalent bonds. Under an action of thermo-mechanical stresses, Au and Al, Cr, Ag and other metals are mutually melted at a contact surface (as shown in the position A of FIG. 1) of the intermediate layer 014 and the first electrical connection layer 006 below the first electrode 011, which is further likely to cause high voltage of the chip, and even the risk of wire-bonding lift-off at a N electrode (i.e., the first electrode 011), resulting in loss of appearance and electrical yield.

In view of the above defects, the disclosure provides a light-emitting diode to solve the technical problems in the related art. The technical solution of the disclosure will be clearly and completely described below through various specific implementation methods in conjunction with drawings in the embodiments of the disclosure.

FIG. 2 illustrates a schematic sectional diagram of the light-emitting diode of the embodiment. The light-emitting diode includes a substrate 008 and a multi-layer structure on the substrate 008. The multi-layer structure, starting from a side of the substrate 008, sequentially includes at least a first electrical connection layer 006, an insulating layer 005, a second electrical connection layer 004 and a semiconductor light-emitting sequence. The light-emitting diode further includes a first electrode 011 and a second electrode 012 used for external bonding connection. The semiconductor light-emitting sequence, the first electrode 011 and the second electrode 012 are located on a same side of the substrate 008.

The substrate 008 is used to support the semiconductor light-emitting sequence, which is generally an insulation substrate, such as aluminum nitride (AlN) and aluminum oxide (Al₂O₃).

The semiconductor light-emitting sequence, starting from a side far away from the substrate 008, sequentially includes a first semiconductor layer 001, an active layer 002 and a second semiconductor layer 003. The first semiconductor layer 001 and the second semiconductor layer 003 are respectively N-type or P-type semiconductor layers, and each including at least a layer that provides electrons or holes to the active layer 002. The active layer 002 is a layer that at least provides semiconductor light emission radiation.

The first electrical connection layer 006 is a conductive layer or a multilayer stacked conductive layer, and is electrically connected to the first semiconductor layer 001. The first electrical connection layer 006 can be formed by stacking at least one conductive material selected from metals or metal alloys, or a combination thereof.

The insulating layer 005 is made of an insulation medium, which is at least one layer of dielectric material, commonly made of inorganic nitrides, oxides or fluorides, and is used at least for insulation between the first electrical connection layer 006 and the second electrical connection layer 004.

The second electrical connection layer 004 is a conductive layer or a multilayer conductive layer, and is located on a side of the second semiconductor layer 003. The second electrical connection layer 004 is electrically connected to the second semiconductor layer 003, and extends horizontally to a lower part of the second electrode 012 to contact with the second electrode 012. The second electrical connection layer 004 is used for electrical connection between the second semiconductor layer 003 and the second electrode 012. The second electrical connection layer 004 can be formed by stacking at least one conductive material selected from metals or metal alloys, or a combination thereof. A reflective layer can be further disposed between the second electrical connection layer 004 and the second semiconductor layer 003. The reflective layer can reflect optical radiation from a light-emitting layer, which has a reflectivity of at least 50%. In an embodiment, the reflectivity can be achieved above 80%. The reflective layer is made of a material with a high reflectivity, for example, a reflective metal or a combination of the reflective metal and a translucent inorganic compound layer. A transparent conductive layer can be further disposed between the reflective layer and the second semiconductor layer 003, and the transparent conductive layer is made of a transparent conductive material, such as indium tin oxide (ITO), so that an ohmic contact problem between the second electrical connection layer 004 and the second semiconductor layer 003 is solved.

In an embodiment, the semiconductor light-emitting sequence includes at least one first through hole 009, and the first through hole 009 defines an opening from a side of the second semiconductor layer 003, and extends through the second semiconductor layer 003 and the active layer 002 to the first semiconductor layer 001. The insulating layer 005 extends from the opening of the first through hole 009 on a side of the second electrical connection layer 004 to cover a sidewall inside the first through hole 009, and expose a bottom of the first through hole 009.

The light-emitting diode further includes an intermediate layer 014 disposed between the substrate 008 and the first electrode 011. The intermediate layer 014 is in contact with the first electrode 011, and a material of the intermediate layer 014 is the same as that of the second electrical connection layer 004.

The light-emitting diode includes at least one second through hole 010, and the second through hole 010 defines an opening on a side of the insulating layer 005, and extends through the insulating layer 005 to the intermediate layer 014. The second through hole 010 exposes a portion of a surface of the intermediate layer 014.

The first electrical connection layer 006 covers a side of the insulating layer 005, is filled in the first through hole 009 to the bottom of the first through hole 009 to electrically contact with the first semiconductor layer 001. The first electrical connection layer 006 is not filled in the second through hole 010, and exposes the opening of the second through hole 010.

The light-emitting diode further includes a metal protective layer 013. The metal protective layer 013 covers a side of the first electrical connection layer 006, passes through the first electrical connection layer 006, and is filled in the second through hole 010 to the bottom of the second through hole 010 to contact with the intermediate layer 014, thereby achieving the electrical connection between the first electrode 011 and the first semiconductor layer 001.

A bonding layer 007 is further disposed between the metal protective layer 013 and the substrate 008. The bonding layer 007 is used to connect a side of the metal protective layer 013 with the substrate 008. The bonding layer 007 can be a layer or a multilayer stacked metal material, at least including one of metal materials, such as titanium (Ti), Nickel (Ni), tin (Sn) and Au.

### Embodiment 1

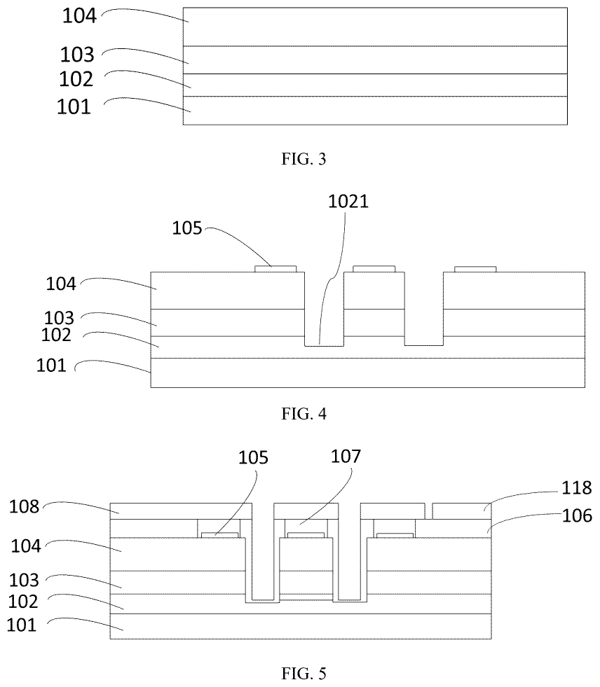

A structure of the light-emitting diode of the embodiment is illustrated in conjunction with a manufacturing method below. FIGS. 3-11 illustrate schematic structural diagrams of structures obtained by steps in a manufacturing method of the light-emitting diode.

Firstly, a semiconductor epitaxial layer is provided. As shown in FIG. 3, the semiconductor epitaxial layer includes a growth substrate 101 and a semiconductor light-emitting sequence. The growth substrate 101 can be an epitaxial growth substrate, such as sapphire, silicon (Si), gallium phosphide (GaP), gallium arsenide (GaAs), indium phosphide (InP) and the like, which can be used to grow the semiconductor light-emitting sequence. In an embodiment, the growth substrate 101 is the sapphire in the embodiment.

The semiconductor light-emitting sequence, starting from a side far away from the growth substrate 101, sequentially includes a first semiconductor layer 102, an active layer 103 and a second semiconductor layer 104. The first semiconductor layer 102 and the second semiconductor layer 104 are respectively N-type or P-type semiconductor layers, and each including at least a layer that provides electrons or holes to the active layer 103. The active layer 103 is a layer that at least provides semiconductor light emission radiation, which can be a single quantum well (QW) layer or a multiple quantum well (MQW) layer. In an embodiment, the first semiconductor layer 102 in the embodiment is a n-type dopant, for example, n-type dopants of Si, germanium (Ge) or Sn. The second semiconductor layer 104 is a p-type dopant, for example, p-type dopants of magnesium (Mg), zinc (Zn), calcium (Ca), strontium (Sr) or barium (Ba).

Then, a first through hole 1021 is opened on a side of the semiconductor light-emitting sequence. As shown in FIG. 4, an opening of the first through hole 1021 is located on a side of the second semiconductor layer 104, and the first through hole 1021 passes through the second semiconductor layer 104 and the active layer 103 to extend into a portion of the first semiconductor layer 102. The first through hole 1021 may be one or more in quantity, and can be set as needed according to a size of the semiconductor light-emitting sequence. A diameter of the first through hole 1021 is in a range of 1 micron (μm) to 100 μm, and a shortest distance between adjacent first through holes 1021 is in a range of 5 μm to 500 μm, which can ensure that the light-emitting diode has good current diffusion.

A transparent conductive layer 105 can be manufactured before manufacturing a second electrical connection layer 108. The transparent conductive layer 105 covers the side of the second semiconductor layer 104, and is in contact with the second semiconductor layer 104, to improve current spreading of the second electrical connection layer 108 for subsequent manufacturing. The transparent conductive layer 105 can be a conductive metal oxide, for example, ITO, indium zinc oxide (IZO) and zinc oxide (ZNO).

In an embodiment, a metal reflective layer 107 can be manufactured, which is used to reflect light radiating by the semiconductor light-emitting sequence. As shown in FIG. 5, the metal reflective layer 107 is manufactured to cover a surface of the transparent conductive layer 105. The metal reflective layer 107 can be made of single or multiple layers of metal, including at least one high reflectivity metal such as Al, Au, Ag and Cr, with a reflectivity greater than 80%. A thickness of the metal reflective layer 107 can be in a range of 50 nanometers (nm) to 500 nm, which can ensure that the metal reflective layer 107 has sufficient reflective ability to reflect the light emitted by the semiconductor light-emitting sequence without increasing too much cost.

In an embodiment, as shown in FIG. 5, a layer of a second insulating layer 106 can be additionally disposed on a side of the second semiconductor layer 104. The second insulating layer 106 at least covers the side of the second semiconductor layer 104, and the sidewall and the bottom of the first through hole 1021. The second insulating layer 106 can be manufactured after manufacturing the transparent conductive layer 105 and before manufacturing the metal reflective layer 107. The second insulating layer 106 can be a nitride or an oxide, such as silicon oxide or silicon nitride. The second insulating layer 106 needs to define one or multiple openings and expose the transparent conductive layer 105, and the metal reflective layer 107 is filled in the opening of the second insulating layer 106 and is in contact with the transparent conductive layer 105.

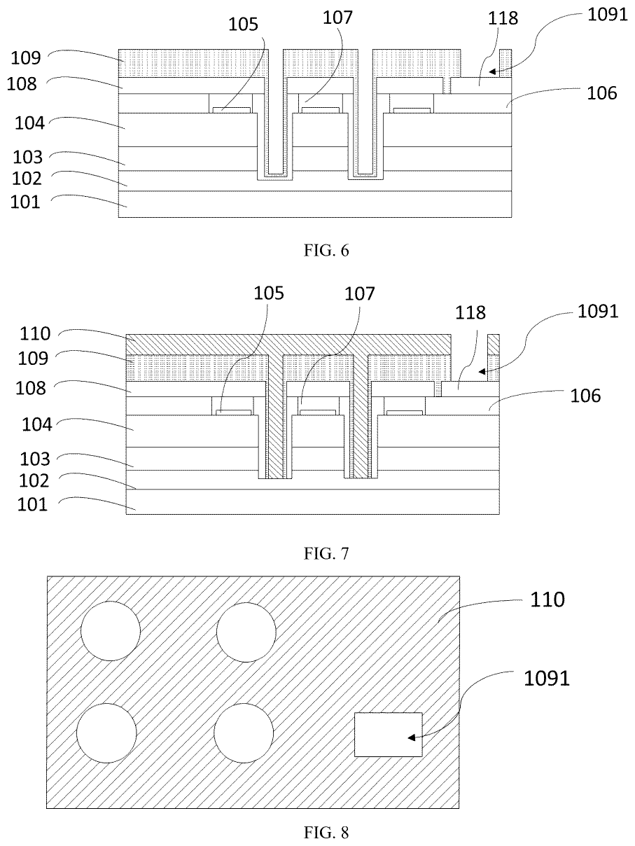

In an embodiment, a second electrical connection layer 108 is manufactured. As shown in FIG. 6, the second electrical connection layer 108 covers the metal reflective layer 107 and a surface of a side of the second insulating layer 106, and does not cover the second insulating layer 106 on a surface of the first through hole 1021. The second electrical connection layer 108 can be a single metal layer or a multilayer metal stacked layer, including at least Au, as well as metals such as platinum (Pt), Cr, Ti, or their alloys. A total thickness of the second electrical connection layer 108 can be in a range of 100 nm to 1000 nm. The second electrical connection layer 108 is not only used for the electrical connection between a second electrode 115 and the second semiconductor layer 104, but also for preventing the diffusion of reflective metals such as Al and Ag from the metal reflective layer 107 to other layers manufactured later. An intermediate layer 118 can be manufactured at the same time as the second electrical connection layer 108. The intermediate layer 118 is located on a side of the second insulating layer 106, and close to an edge area of the second insulating layer 106. The intermediate layer 118 and the second electrical connection layer 108 are separated from each other in the horizontal direction, and a material of the intermediate layer 118 is the same as that of the second electrical connection layer 108.

As shown in FIG. 7, a first insulating layer 109 is manufactured to cover the bottom of the first through hole 1021, the sidewall of the first through hole 1021 and the side of the second electrical connection layer 108, the first insulating layer 109 is filled into a separation region between the second electrical connection layer 108 and the intermediate layer 118, and a material of the first insulating layer 109 can be the same as or different from that of the second insulating layer 106. Specifically, the material of the first insulating layer 109 can be an oxide or a nitride, such as silicon oxide, silicon nitride, zinc oxide and other electrically insulating materials.

After manufacturing the first insulating layer 109, at least a portion of the first insulating layer 109 and the second insulating layer 106 on the bottom of the first through hole 1021 are removed by an etching process to expose the first semiconductor layer 102. The etching process can be inductively coupled plasma (ICP) etching. Meanwhile, a second through hole 1091 is defined by etching an opening on a side of the first insulating layer 109 corresponding to a subsequent manufacturing position of the first electrode 114. The second through hole 1091 is located on a portion of the first insulating layer 109 above the intermediate layer 118, and the second through hole 1091 is cylindrical or conical in shape.

In an embodiment, a first electrical connection layer 110 is manufactured. The first electrical connection layer 110 covers a surface of the first insulating layer 109, and is filled from the opening of the first through hole 1021 to the bottom of the first through hole 1021, to achieve the electrical connection of the first electrode 114. The first electrical connection layer 110 is not filled in the second through hole 1091, and an opening is reserved at a corresponding position of the second through hole 1091. As shown in FIGS. 7-8, FIG. 7 illustrates a schematic diagram from a top perspective of a side of the first electrical connection layer 110. The first electrical connection layer 110 can be a single layer or multiple layers of metal with good conductivity and high reflectivity, with a reflectivity of at least 50%. In an embodiment, the reflectivity can be achieved above 80%, such as at least one metal or alloy of Al, Ni, Cr, and Ag. In an embodiment, the first electrical connection layer 110 is an Al/Cr stacked layer.

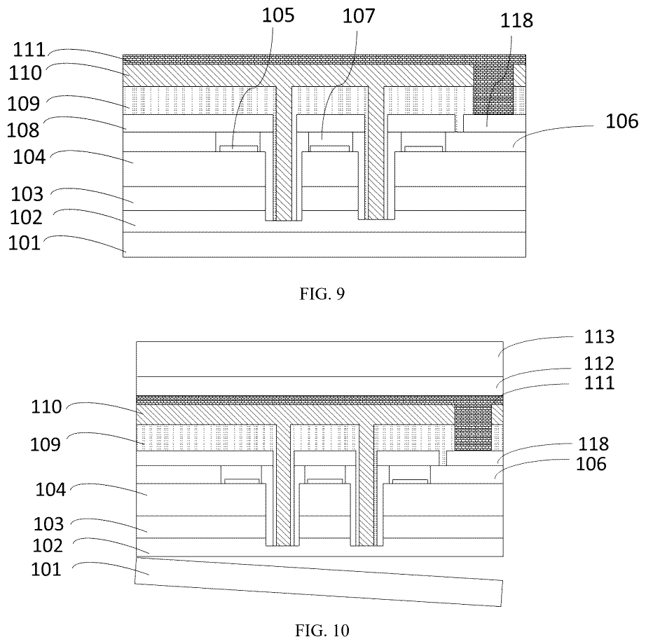

In an embodiment, a metal protective layer 111 is manufactured. As shown in FIG. 9, the metal protective layer 111 covers a surface of the first electrical connection layer 110, and is filled from the opening of the second through hole 1091 to the bottom of the second through hole 1091 to contact with the intermediate layer 118. In this way, the intermediate layer 118 can be isolated from the first electrical connection layer 110, avoiding the contact between the intermediate layer 118 and the first electrical connection layer 110, thereby preventing the metal material of the intermediate layer 118, such as Au, from fusing with the reflective metals of the first electrical connection layer 110, such as Al and Cr, in the subsequent bonding process due to high temperature and high voltage, resulting in high voltage of the final chip, and even the risk of wire-bonding lift-off at the first electrode 114, leading to loss of appearance and electrical yield. The metal protective layer 111 can be a single layer or multiple layers of conductive metal with stable performance, such as Ti and tungsten (W), including an alloy of at least one of them. In the embodiment, a double-layer stacked structure of Ti and TiW is used, the Ti layer is the first layer, which can facilitate the adhesion of the second layer of TiW and the intermediate layer 118. The second layer of TiW has good stability, and in addition to preventing the metal of the intermediate layer 118 from contacting and fusing with the metal of the first electrical connection layer 110, it can also prevent the metal of the first electrical connection layer 110 from diffusing to the bonding layer 112 manufactured subsequently. In an embodiment, a thickness of the metal protective layer 111 between the first electrical connection layer 110 and the bonding layer 112 manufactured subsequently is in a range of 50 nm to 300 nm, so that the metal protective layer 111 can prevent the metal of the first electrical connection layer 110 from diffusing without increasing the cost too much.

In an embodiment, the bonding layer 112 is manufactured. A bonding metal is simultaneously deposited on a surface of the metal protective layer 111 and a surface of an insulation substrate 113, and the bonding metal on the surface of the metal protective layer 111 and the bonding metal on the surface of the insulation substrate 113 are bonded together by a high-temperature bonding process to form the metal bonding layer 112. As shown in FIG. 10, the insulation substrate 113 covers a surface of the metal bonding layer 112 to provide support for the light-emitting diode. The metal of the metal bonding layer 112 can be one or a combination of conventional bonding materials such as gold tin, nickel tin, or titanium nickel tin.

Then, the growth substrate 101 is removed. As shown in FIG. 10, the growth substrate 101 can be removed by grinding and thinning, laser stripping, wet etching, dry etching or a combination of other processes according to the material. For example, the sapphire substrate is removed by grinding and thinning and laser stripping.

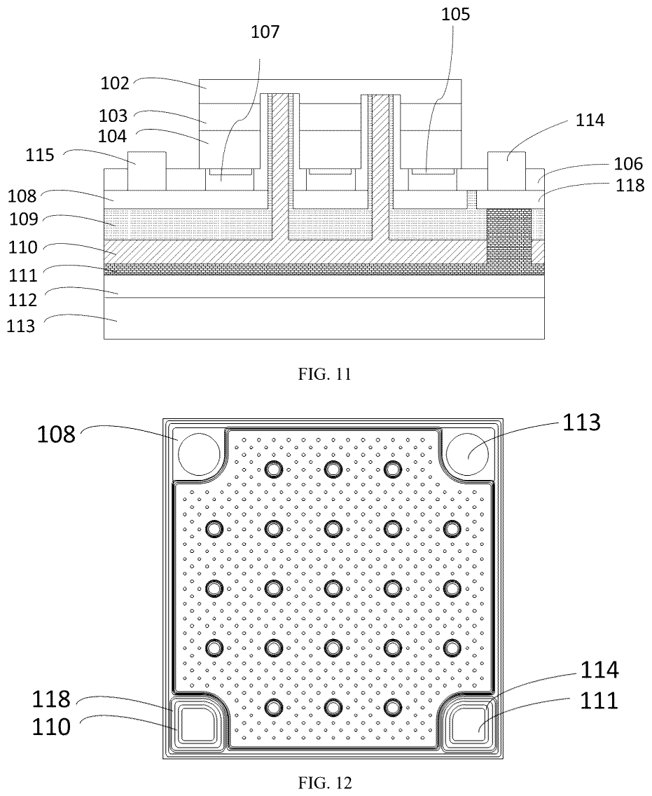

In an embodiment, the semiconductor light-emitting sequence is etched from a side of the first semiconductor layer 102 until a portion of the second electrical connection layer 108 and the intermediate layer 118 are exposed. As shown in FIG. 11, the exposed surface of the second electrical connection layer 108 is used to manufacture the second electrode 115, and the exposed surface of the intermediate layer 118 is used to manufacture the first electrode 114. In an embodiment, a contact area between the intermediate layer 118 and the first electrode 114 is greater than a contact area between the intermediate layer 118 and the metal protective layer 111. The surface of the first semiconductor layer 102 of the semiconductor light-emitting sequence can be roughened to form a light-emitting surface to improve the light-emitting efficiency. At least a top or a sidewall of the light-emitting surface can form a light-transmitting protective layer, and the protective layer can be made of materials such as silicon oxide and silicon nitride to form water vapor or electrical insulation protection.

The first electrode 114 and the second electrode 115 are manufactured. The first electrode 114 and the second electrode 115 can be a single one or at least two. The first electrode 114 and the second electrode 115 are respectively manufactured on the surfaces of the second electrical connection layer 108 and the intermediate layer 118 and can be manufactured to the same height to facilitate the subsequent wire bonding process.

Finally, a single light-emitting diode with completely separated sidewalls and bottom is formed from the semiconductor light-emitting sequence side to the insulation substrate 113 through a separation process, as shown in FIG. 11. FIG. 12 illustrates a schematic diagram from a top perspective of a separated light-emitting diode. The separation process includes an etching process of the semiconductor light-emitting sequence, the first electrical connection layer, the insulating layer, and the second electrical connection layer, and a cutting process of the substrate. In an embodiment, a projection of the second through hole 1091 on the substrate 113 at least partially overlaps with a projection of the intermediate layer 118 on the substrate 113, and does not overlap with a projection of the second electrical connection layer 108 on the substrate 113, so as to ensure that the metal protective layer 111 plays a sufficient conductive role and does not contact the second electrical connection layer 108 to cause a short circuit.

### Embodiment 2

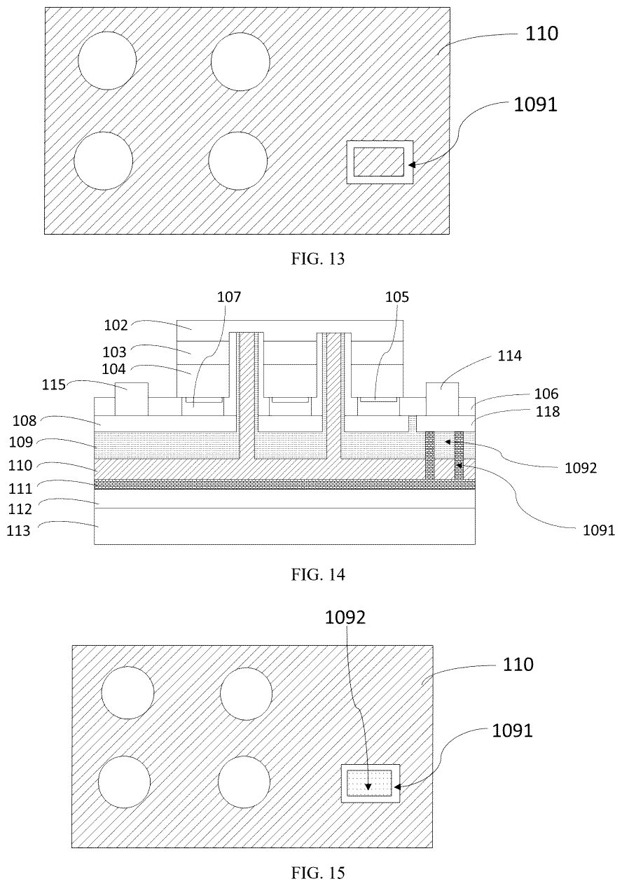

As an alternative to the embodiment 1, in this embodiment, the second through hole 1091 is designed as a closed loop structure, and an independent insulating layer 1092 is disposed in a middle of the second through hole 1091. The independent insulating layer 1092 is also covered by the first electrical connection layer 110. The annular second through hole 1091 is also filled with the metal protective layer 111, as shown in FIGS. 13 and 14. FIG. 13 illustrates a schematic diagram from a top perspective of a side of the first electrical connection layer 110. The other structures are consistent with the embodiment 1. The schematic diagram of the formed light-emitting diode is shown in FIG. 13. A side of the independent insulating layer 1092 will be used to provide the main support or all support for the first electrode 114, that is, the independent insulating layer 1092 will be designed to be located below the first electrode 114 in the subsequent manufacturing steps. When a surface side of the first electrode 114 is subjected to external force for wire bonding, the external force is mainly concentrated at a center of the first electrode 114. The independent insulating layer 1092 can be used to block the main wire bonding force from the wire bonding electrode (such as a gold ball). The annular second through hole 1091 will be disposed to deviate from a central position below the second electrode 115, and around the independent insulating layer 1092. A portion of the metal protective layer 111 filled in the second through hole 1091 that is subjected to a smaller wire bonding force or is not subjected to vertical wire bonding force, thereby preventing the metal protective layer 111 filled in the second through hole 1091 from collapsing and causing wire bonding abnormalities.

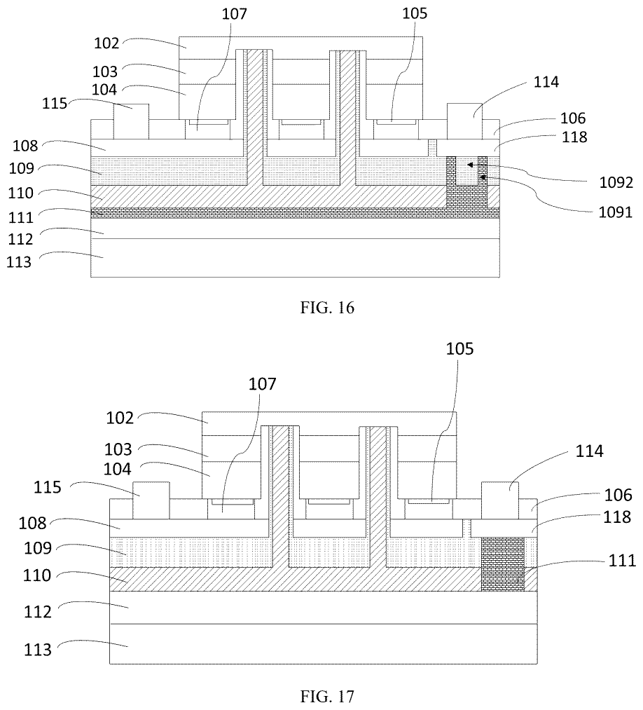

In an optional embodiment, the surface of the independent insulating layer 1092 is not covered by the first electrical connection layer 110, but is covered by the metal protective layer 111, and the annular second through hole 1091 is also filled with the metal protective layer 111. As shown in FIGS. 15-16, FIG. 15 illustrates a schematic diagram from a top perspective of a side of the first electrical connection layer 110, and the other structures are consistent with the embodiment 1. The schematic diagram of the formed light-emitting diode is shown in FIG. 16.

### Embodiment 3

As an alternative to the embodiment 1, the metal protective layer 111 in this embodiment is only filled in the second through hole 1091 to the bottom of the second through hole 1091 to contact the intermediate layer 118, and does not cover the surface of the first electrical connection layer 110, as shown in FIG. 17, so that the metal of the intermediate layer 118 can be prevented from contacting and fusing with the metal of the first electrical connection layer 110, and the evaporation cost of the metal protective layer 111 can be reduced. In an embodiment, the second through hole 1091 is at least one in quantity, which can be cylindrical, annular or conical. The other structures are consistent with the embodiment 1.

### Embodiment 4

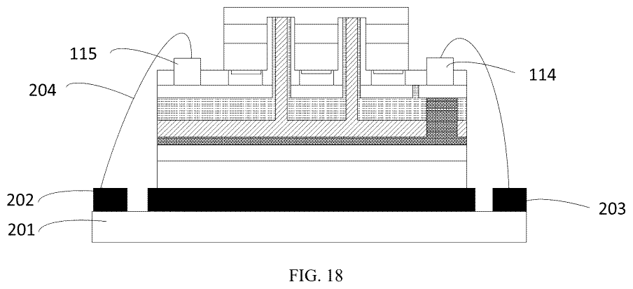

The light-emitting diode of the disclosure can be used to manufacture packaged products or widely used lighting or augmented reality (AR) fields with high current requirements. The embodiment provides a light-emitting device including the light-emitting diode. As shown in FIG. 18, a package substrate 201 is provided, a conductive circuit layer is disposed on the package substrate 201, and a lower side of the insulation substrate of the light-emitting diode of each of the embodiment 1 to 3 is mounted on the package substrate 201 by an adhesive. The conductive circuit layer is at least two parts 202 and 203 (i.e., the two conductive layers) insulated from each other, which are used for external bonding connection of the first electrode 114 and the second electrode 115. Surfaces of the first electrode 114 and the second electrode 115 are connected to the conductive circuit layer by metal wires 204. The surface of the light-emitting diode and the surface of the package substrate 201 can also be covered and packaged with a package resin or a package resin doped with phosphor.

The above description is merely some of the embodiments of the disclosure and is not intended to limit the disclosure. Any modifications, equivalent substitutions, and improvements made within a spirit and a principle of the disclosure should be included in a protection scope of the disclosure.

What is claimed is:

1. A light-emitting diode, comprising:
a substrate;
a multi-layer structure, stacked on the substrate, wherein the multi-layer structure, starting from a side of the substrate, sequentially comprises at least a first electrical connection layer, an insulating layer, a second electrical connection layer and a semiconductor light-emitting sequence; the semiconductor light-emitting sequence, starting from a side far away from the substrate, sequentially comprises a first semiconductor layer, an active layer and a second semiconductor layer; the first electrical connection layer is at least partially in contact with the first semiconductor layer; and the second electrical connection layer is electrically connected to the second semiconductor layer;
a first electrode, electrically connected to the first semiconductor layer through the first electrical connection layer;
a second electrode, electrically connected to the second semiconductor layer through the second electrical connection layer, wherein the semiconductor light-emitting sequence, the first electrode and the second electrode are disposed on a same side of the substrate;
an intermediate layer, located between the substrate and the first electrode, wherein at least a portion of a surface of the intermediate layer is in contact with the first electrode; and
a metal protective layer, wherein the metal protective layer extends from at least one side of the first electrical connection layer through the first electrical connection layer and the insulating layer to contact with the intermediate layer, and the metal protective layer comprises at least one metal element different from the first electrical connection layer.

2. A light-emitting diode, comprising:
a substrate;
a multi-layer structure, stacked on the substrate, wherein the multi-layer structure, starting from a side of the substrate, sequentially comprises at least a first electrical connection layer, an insulating layer, a second electrical connection layer and a semiconductor light-emitting sequence; the semiconductor light-emitting sequence, starting from a side far away from the substrate, sequentially comprises a first semiconductor layer, an active layer and a second semiconductor layer; the first electrical connection layer is at least partially in contact with the first semiconductor layer; and the second electrical connection layer is electrically connected to the second semiconductor layer;
a first electrode, electrically connected to the first semiconductor layer through the first electrical connection layer;
a second electrode, electrically connected to the second semiconductor layer through the second electrical connection layer, wherein the semiconductor light-emitting sequence, the first electrode and the second electrode are disposed on a same side of the substrate;
an intermediate layer, located between the substrate and the first electrode, wherein at least a portion of a surface of the intermediate layer is in contact with the first electrode, and the insulating layer defines an opening exposing the at least a portion of the surface of the intermediate layer; and
a metal protective layer, filled in the opening and in contact with the intermediate layer.

3. The light-emitting diode as claimed in claim 1, wherein the metal protective layer further covers a surface of a side of the first electrical connection layer close to the substrate.

4. The light-emitting diode as claimed in claim 1, wherein the metal protective layer is formed by staking single or multiple layers of metal.

5. The light-emitting diode as claimed in claim 1, wherein the metal protective layer comprises at least a metal element tungsten.

6. The light-emitting diode as claimed in claim 1, wherein the semiconductor light-emitting sequence comprises at least one first through hole, an opening of the at least one first through hole is located on a side of the second semiconductor layer, and a bottom of the at least one first through hole is in contact with the first semiconductor layer; and the first electrical connection layer is filled to the bottom of the at least one first through hole through the opening of the at least one first through hole, and a sidewall of the at least one first through hole is insulated through the insulating layer.

7. The light-emitting diode as claimed in claim 1, wherein the light-emitting diode comprises at least one second through hole, an opening of the at least one second through hole is located on a side of the first electrical connection layer, and a bottom of the at least one second through hole is in contact with the intermediate layer; and the metal protective layer is filled to the bottom of the at least one second through hole through the opening of the at least one second through hole to contact with the intermediate layer.

8. The light-emitting diode as claimed in claim 7, wherein the at least one second through hole is cylindrical, conical, or annular.

9. The light-emitting diode as claimed in claim 7, wherein a projection of the at least one second through hole on the substrate at least partially overlaps with a projection of the intermediate layer on the substrate, and does not overlap with a projection of the second electrical connection layer on the substrate.

10. The light-emitting diode as claimed in claim 7, wherein the at least one second through hole is not located at a center position below the first electrode.

11. The light-emitting diode as claimed in claim 1, further comprising:
a bonding layer, located between the first electrical connection layer and the substrate.

12. The light-emitting diode as claimed in claim 11, wherein a thickness of the metal protective layer between the first electrical connection layer and the bonding layer is in a range of 50 nanometers (nm) to 300 nm.

13. The light-emitting diode as claimed in claim 1, wherein a metal reflective layer and a transparent conductive layer are disposed between the second electrical connection layer and the second semiconductor layer.

14. The light-emitting diode as claimed in claim 1, wherein the first electrical connection layer and the second electrical connection layer each are formed by staking single or multiple layers of metal.

15. The light-emitting diode as claimed in claim 1, wherein a material of the intermediate layer is the same as that of the second electrical connection layer.

16. The light-emitting diode as claimed in claim 1, wherein the first electrical connection layer comprises at least one metal with a reflectivity greater than 80%.

17. The light-emitting diode as claimed in claim 2, wherein the metal protective layer is formed by staking single or multiple layers of metal.

18. The light-emitting diode as claimed in claim 2, wherein the metal protective layer comprises at least a metal element tungsten.

19. The light-emitting diode as claimed in claim 2, further comprising: a bonding layer, located between the first electrical connection layer and the substrate, wherein a thickness of the metal protective layer between the first electrical connection layer and the bonding layer is in a range of 50 nm to 300 nm.

20. A light-emitting device, comprising a package substrate, wherein a surface of the package substrate comprises at least two conductive layers insulated from each other, the light-emitting diode as claimed in claim 1 is fixed on the surface of the package substrate, the first electrode and the second electrode are respectively connected to the at least two conductive layers insulated from each other through metal wires, and the surface of the package substrate and a surface of the light-emitting diode are covered with a package resin.
